(19) United States
(12) Patent Application Publication
(10) Pub. No.: US 2026/0360449 A1
(43) Pub. Date: Nov. 12, 2026

(54) MEMORY DEVICE AND PROGRAMMING METHOD THEREOF

(71) Applicant: MACRONIX International Co., Ltd., Hsinchu (TW)

(72) Inventors: You-Liang Chou, Taichung City (TW); Wen-Che Tsai, Hualien City (TW)

(73) Assignee: MACRONIX International Co., Ltd., Hsinchu (TW)

(21) Appl. No.: 19/200,685

(22) Filed: May 7, 2025

(51) Int. Cl. G11C 16/34; G11C 16/04; G11C 16/08; G11C 16/10; G11C 16/24

(52) U.S. Cl. CPC G11C 16/3427; G11C 16/0483; G11C 16/08; G11C 16/102; G11C 16/24

(57) ABSTRACT

Disclosed are a memory device and a programming method thereof. The memory device is, for example a three-dimensional NAND flash memory, and provides a storage media with high-performance and high-capacity. The programming method includes: setting one of the first memory cell strings as a selected memory cell string, in a first phase, setting a first bit line voltage on the first common bit line to be within a first set voltage range, and setting a second bit line voltage on the second common bit line to be higher than the first set voltage range; and, in a second phase, providing a programming voltage to the word line corresponding to the selected memory cell on the selected memory cell string.

### BACKGROUND

### Technical Field

The present disclosure relates to a memory device and a programming method thereof, and particularly relates to a memory device and a programming method that may enhance the programming action rate.

### Description of Related Art

In order to enhance the storage density of memory devices, three-dimensional multi-memory cell string NAND flash memory devices have been proposed. This type of memory device has multiple memory cell strings, and when executing programming actions on selected memory cells, due to the high-density configuration relationship of multiple memory cell strings, the programming action performed on the selected memory cells often affects nearby unselected memory cells. Therefore, how to enhance the programming performance of selected memory cells, while effectively masking unselected memory cells to prevent them from being affected by the programming action, is an important issue for those skilled in the field.

### SUMMARY

The present disclosure provides a memory device and a programming method thereof, which may reduce the operation time required for programming action.

The programming method of the memory device in the present disclosure includes: setting, among multiple memory cell strings, multiple first memory cell strings arranged along a first direction to be coupled to the same first common bit line, multiple second memory cell strings arranged along the first direction to be coupled to the same second common bit line; setting, among multiple memory cell strings, multiple third memory cell strings arranged along a second direction to be coupled to the same first common source line, multiple fourth memory cell strings arranged along the second direction to be coupled to the same second common source line, wherein the first direction is different from the second direction; setting one of the first memory cell strings as a selected memory cell string, in a first phase, setting a first bit line voltage on the first common bit line to be within a first set voltage range, and setting a second bit line voltage on the second common bit line to be higher than the first set voltage range; and, in a second phase, providing a programming voltage to the word line corresponding to the selected memory cell on the selected memory cell string.

The memory device in the present disclosure includes multiple memory cell strings and a controller. The controller is coupled to the memory cell strings and utilized to execute the aforementioned programming action.

Based on the above, the memory device in the present disclosure, through setting the first bit line voltage on the first common bit line to be within a relatively low first set voltage range, and setting the second bit line voltage on the second common bit line to be higher than the first set voltage range in the same phase, completes both the channel discharge of the selected memory cell string and the Gate-Induced-Drain-Leakage (GIDL) boost action in the same phase. In this way, it is possible to effectively reduce the time required to execute the programming action, enhancing the operating performance of the memory device.

### BRIEF DESCRIPTION OF THE DRAWINGS

FIG. 1 illustrates a schematic diagram of a memory device according to an implementation method of the present disclosure.

FIG. 2A illustrates a schematic diagram of the positional relationship between selected memory cells and unselected memory cells according to an embodiment of the present disclosure.

FIG. 2B illustrates a waveform diagram of the programming action of the memory device according to an embodiment of the present disclosure.

FIG. 3 illustrates a schematic diagram of an implementation of memory cell strings according to an embodiment of the present disclosure.

FIG. 4 illustrates a flowchart of the programming action of the memory device according to an embodiment of the present disclosure.

### DESCRIPTION OF THE EMBODIMENTS

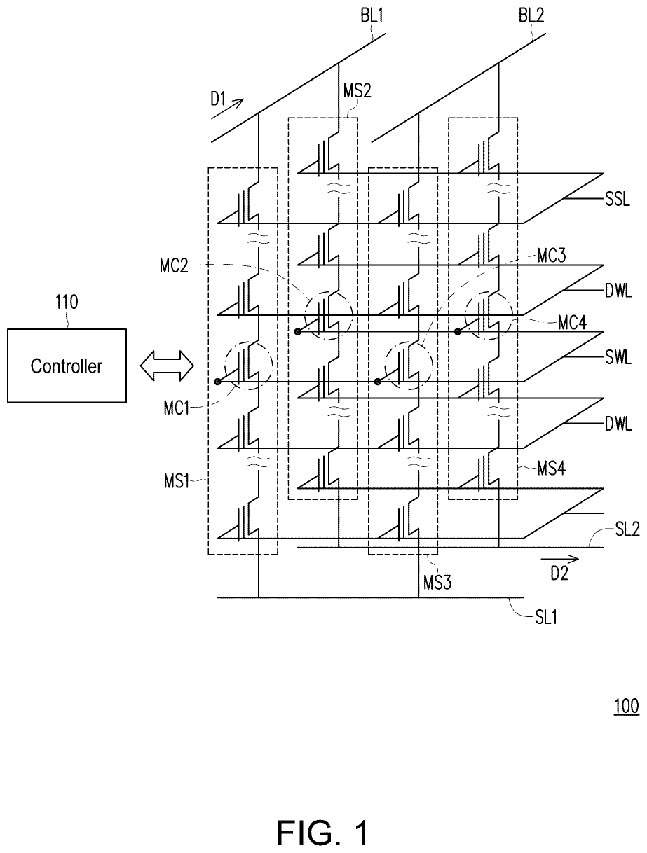

Please refer to FIG. 1, FIG. 1 illustrates a schematic diagram of a memory device according to an embodiment of the present disclosure. The memory device 100 includes multiple memory cell strings MS1 to MS4 and a controller 110. The memory cell strings MS1 and MS2 are arranged along a direction D1, and are commonly coupled to a common bit line BL1 which also extends along the direction D1. The memory cell strings MS3 and MS4 are similarly arranged along the direction D1, and are commonly coupled to a common bit line BL2 which extends along the direction D1. On the other hand, the memory cell strings MS1 and MS3 are arranged along a direction D2, and are commonly coupled to a common source line SL1 which also extends along the direction D2. The memory cell strings MS2 and MS4 are arranged along the direction D2, and are commonly coupled to a common source line SL2 which also extends along the direction D2. The controller 110 is coupled to the memory cell strings MS1 to MS4.

In this embodiment, the memory cell strings MS1 to MS4 may be set up in a three-dimensional stacked manner. Each memory cell string MS1 to MS4 has multiple serially connected memory cell string selection switches, memory cells, and ground selection switches. The memory cell string selection switches of the memory cell strings MS1 to MS4 may be commonly controlled by the memory cell string selection signal SSL. The ground selection switches of the memory cell strings MS1 to MS4 may be commonly controlled by a ground selection signal GSL. Multiple memory cells in the memory cell strings MS1 to MS4 are respectively coupled to multiple word lines, wherein the memory cells (for example, memory cells MC1 to MC4) at corresponding positions on the memory cell strings MS1 to MS4 may be coupled to the same word line.

When executing the programming action, the controller 110 may set one of the memory cell strings MS1 to MS4 as the selected memory cell string, and set one memory cell in the selected memory cell string as the selected memory cell. Taking the memory cell string MS1 as the selected memory cell string and the memory cell MC1 as the selected memory cell for example, the word lines of the memory cell MC1 and the corresponding memory cells MC2 to MC4 may receive a same selected word line signal SWL, while the word lines of the remaining memory cells may receive an unselected word line signal DWL.

Under the condition that the memory cell MC1 is the selected memory cell, the common source line SL1 coupled to the memory cell string MS1 of the selected memory cell string may be the selected source line, and the common bit line BL1 coupled to the memory cell string MS1 of the selected memory cell string may be the selected bit line. The common source line SL2 may be the unselected source line, and the common bit line BL2 may be the unselected bit line.

In this embodiment, the controller 110 may be a processor with computing capability. Alternatively, the controller 110 may be designed through Hardware Description Language (HDL) or any other digital circuit design familiar to those with ordinary knowledge in this field, and implemented as hardware circuits through Field Programmable Gate Array (FPGA), Complex Programmable Logic Device (CPLD), or Application-specific Integrated Circuit (ASIC), there are no specific limitations in this regard.

The controller 110 may work with the voltage generator and address decoder inside the memory device 100 to set the required voltage values for each word line, each bit line, and each source line. The relevant implementation details may be carried out according to the methods familiar to those with ordinary knowledge pertaining to memory technology, there are no particular limitations in this regard.

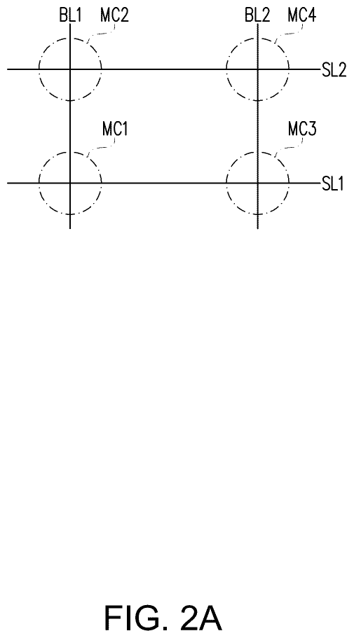

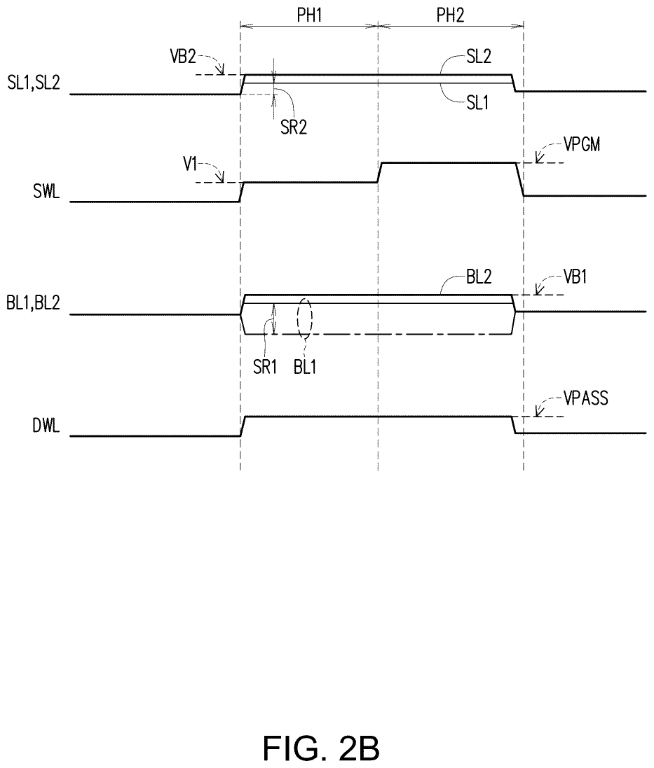

Regarding the execution method of the programming action of the memory device, please refer to FIG. 2A and FIG. 2B, where FIG. 2A illustrates the diagram showing the positional relationship of the selected memory cells and unselected memory cells in an embodiment of the present disclosure, and FIG. 2B illustrates the waveform diagram of the programming action of the memory device in an embodiment of the present disclosure. In FIG. 2A, corresponding to the memory device of the embodiment in FIG. 1, the memory cell MC1 as the selected memory cell is coupled to the common bit line BL1, and coupled to the common source line SL1. For the remaining parts, the memory cell MC2 is coupled to the common bit line BL1, and coupled to the common source line SL2; the memory cell MC3 is coupled to the common bit line BL2, and coupled to the common source line SL1; the memory cell MC4 is coupled to the common bit line BL2, and coupled to the common source line SL2.

In FIG. 2B, in the programming action, during the initial phase before a first phase PH1, the voltages on the common source lines SL1 and SL2, the common bit lines BL1 and BL2, the selected word line SWL, and unselected word line DWL may all be the reference ground voltage (for example, 0 volts). In the first phase PH1, the bit line voltage of the common bit line BL1 set as the selected bit line is set to be within a set voltage range SR1, and the bit line voltage of the common bit line BL2 set as the unselected bit line is set to be a voltage VB1 higher than the set voltage range SR1.

In this embodiment, the set voltage range SR1 may be, for example, between −5 volts and 3 volts, and the voltage VB1 may be, for example, greater than 8 volts. Of course, the values of the set voltage range SR1 and voltage VB1 may be adaptively adjusted according to the circuit manufacturing parameters of the memory device 100 and the magnitude of the applied operating voltage. The values provided in this embodiment are only examples for illustration and are not utilized to limit the implementation scope of the present disclosure.

Also in the first phase PH1, the controller 110 may set the source line voltage on the common source line SL1 set as the selected source line to be within the set voltage range SR2, and set the source line voltage on the common source line SL2 set as the unselected source line to be a voltage VB2 higher than the set voltage range SR2. In this embodiment, the set voltage range SR2 may be, for example, between 0 volts and 4 volts, and the voltage VB2 may be, for example, 8 volts. Of course, the values of the set voltage range SR2 and voltage VB2 may also be adaptively adjusted according to the circuit manufacturing parameters of the memory device 100 and the magnitude of the applied operating voltage. The values provided in this embodiment are only examples for illustration and are not utilized to limit the implementation scope of the present disclosure.

Under this setting, the memory cell MC1 may be set to the selected state, and the memory cells MC2 to MC4 may be set to the masked state. Notably, in the first phase PH1, by setting the common bit line BL1 to have a relatively low voltage value within the set voltage range SR1, the channel of the memory cell string MS1 selected to execute the programming action may perform discharge operation through the common bit line BL1. In the meantime, the controller 110, by providing the common source line SL2 of the unselected source line with a relatively high voltage value source line voltage (=voltage VB2), causes the memory cells MC2 and MC4 of the unselected memory cells to generate gate-induced-drain-leakage current, and through this gate-induced-drain-leakage current to perform a gate-induced-drain-leakage current boost action to increase the voltage on the channels of the memory cells MC2 and MC4, thereby masking the subsequent programming action.

In other words, in the embodiment of the present disclosure, the first phase PH1 is a gate-induced-drain-leakage current boost and channel discharge phase, which may simultaneously perform gate-induced-drain-leakage current boost and channel discharge actions. There is no need to provide an additional channel discharge phase, so that it is possible to effectively save time delay in the programming action of the memory device 100.

In addition, the controller 110 may cause the memory cell MC3 to produce a masking effect through the common bit line BL2 with its bit line voltage pulled high.

On the other hand, in the first phase PH1, the controller 110 may set the selected word line signal SWL to a pre-charge voltage V1, and set the unselected word line signal DWL to a pass voltage VPASS.

Next, in a second phase PH2, the controller 110 may raise the selected word line signal SWL from the pre-charge voltage V1 to the programming voltage VPGM. In this embodiment, the pre-charge voltage V1 may be 7 volts, for example, and the programming voltage VPGM may be 20 volts, for example. The pass voltage VPASS may be 7 volts, for example. Thereby, the programming action may be performed on the memory cell MC1. In this embodiment, the second phase PH2 may be a programming voltage boost phase. Similarly, the voltage values of the pre-charge voltage V1, the pass voltage VPASS, and the programming voltage may also be adjusted by the designer according to actual requirements, there are no specific limitations in this regard.

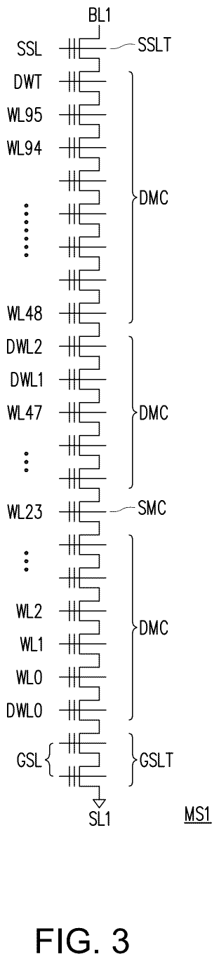

Please refer to FIG. 3 below. FIG. 3 illustrates a schematic diagram of an implementation of a memory cell string according to an embodiment of the present disclosure. Taking the memory cell string MS1 in FIG. 1 as an example, the memory cell string MS1 includes multiple transistors serially connected between the bit line BL1 and the source line SL1. In the memory cell string MS1, the memory cell string selection switch SSLT is coupled to the bit line BL1, the ground selection switch GSLT is coupled to the source line SL1, and multiple memory cells are coupled between the memory cell string selection switch SSLT and the ground selection switch GSLT. In this embodiment, the multiple memory cells sequentially (from top to bottom in the figure) receive the control signal DMT, word line signals WL95 to WL48, dummy word line signals DWL2 and DWL1, word line signals WL47 to WL0, and the dummy word line signal DWL0. When executing the programming action, one memory cell in the memory cell string MS1 may be set as the selected memory cell SMC to execute the programming action, and the remaining memory cells may be unselected memory cells DMC.

In this embodiment, the memory cell string MS1 may be a memory cell string of a NAND flash memory.

Of course, the memory cell string MS1 in FIG. 3 is merely an example for illustration and is not intended to limit the implementation scope of the present disclosure. In practical applications, memory cell strings commonly known to those with ordinary knowledge in this field may all be applied to the present disclosure, there are no specific limitations in this regard.

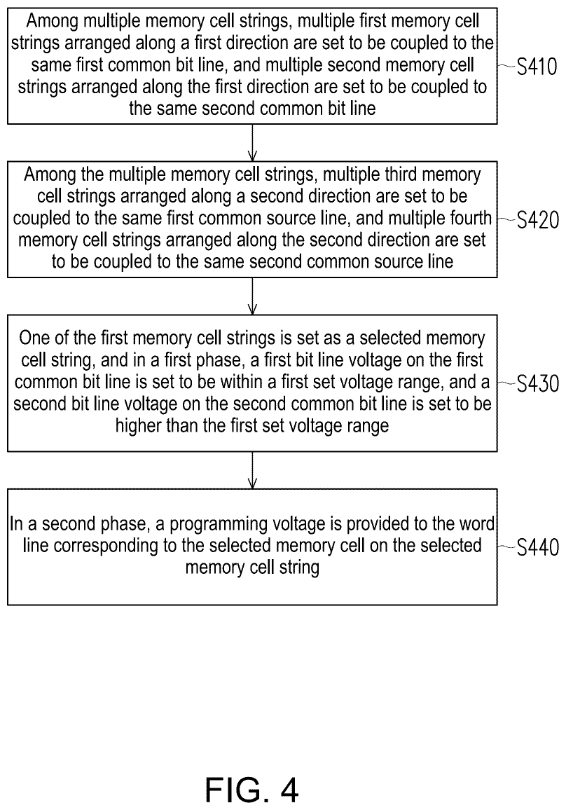

Please refer to FIG. 4, FIG. 4 illustrates a flowchart of a programming action of a memory device according to an embodiment of this disclosure. In step S410, among multiple memory cell strings, multiple first memory cell strings arranged along a first direction may be set to be coupled to the same first common bit line, and multiple second memory cell strings arranged along the first direction may be set to be coupled to the same second common bit line. Moreover, in step S420, among the multiple memory cell strings, multiple third memory cell strings arranged along a second direction may be set to be coupled to the same first common source line, and multiple fourth memory cell strings arranged along the second direction may be set to be coupled to the same second common source line, wherein the first direction is different from the second direction. Furthermore, in step S430, through the controller, one of the first memory cell strings may be set as a selected memory cell string, and in a first phase, a first bit line voltage on the first common bit line may be set to be within a first set voltage range, and a second bit line voltage on the second common bit line may be set to be higher than the first set voltage range. Moreover, also through the controller, in step S440, in a second phase, a programming voltage may be provided to the word line corresponding to the selected memory cell on the selected memory cell string.

Regarding the implementation details of the above steps, detailed explanations have been provided in the aforementioned embodiments, and will not be elaborated further here.

In summary, the memory device of the present disclosure completes the discharge action of the channel of the selected memory cell and the boost action of the channel voltage of the unselected memory cells synchronously in the first phase of the programming action. Thereby, the selection action of the selected memory cell and the masking action of the unselected memory cells may be completed simultaneously. In this way, it is possible to effectively reduce the time consumed by the programming action and enhance the operating performance of the memory device.

What is claimed is:

1. A programming method of a memory device, comprising:
setting, among a plurality of memory cell strings, a plurality of first memory cell strings arranged along a first direction to be coupled to a same first common bit line, a plurality of second memory cell strings arranged along the first direction to be coupled to a same second common bit line;
setting, among the plurality of memory cell strings, a plurality of third memory cell strings arranged along a second direction to be coupled to a same first common source line, a plurality of fourth memory cell strings arranged along the second direction to be coupled to a same second common source line, wherein the first direction is different from the second direction;
setting one of the plurality of first memory cell strings as a selected memory cell string, in a first phase, setting a first bit line voltage on the first common bit line to be within a first set voltage range, and setting a second bit line voltage on the second common bit line to be higher than the first set voltage range; and
in a second phase, providing a programming voltage to a word line corresponding to a selected memory cell on the selected memory cell string.

2. The programming method according to claim 1, wherein in the first phase, setting the first bit line voltage to be within the first set voltage range to discharge a channel of the selected memory cell string.

3. The programming method according to claim 2, further comprising:
determining a voltage value of the first bit line voltage according to a threshold voltage of a memory cell string selection switch of the plurality of first memory cell strings.

4. The programming method according to claim 1, wherein in the first phase, setting the second bit line voltage to be higher than the first set voltage range to mask the plurality of second memory cell strings.

5. The programming method according to claim 1, further comprising:
in the first phase, setting a first source line voltage on the first common source line corresponding to the selected memory cell string to be within a second set voltage range, and setting a source line voltage on the second common bit line to be higher than the second set voltage range.

6. The programming method according to claim 5, wherein the source line voltage on the second common bit line is set to be higher than the second set voltage range to mask the plurality of fourth memory cell strings.

7. The programming method according to claim 1, further comprising:
providing a pass voltage to word lines of a plurality of unselected memory cells in the selected memory cell string.

8. The programming method according to claim 1, wherein the first phase is a gate-induced-drain-leakage current boost and channel discharge phase, and the second phase is a programming voltage boost phase.

9. A memory device, comprising:
a plurality of memory cell strings, wherein among the plurality of memory cell strings, a plurality of first memory cell strings arranged along a first direction are coupled to a same first common bit line, a plurality of second memory cell strings arranged along the first direction are coupled to a same second common bit line, a plurality of third memory cell strings arranged along a second direction are coupled to a same first common source line, a plurality of fourth memory cell strings arranged along the second direction are coupled to a same second common source line, wherein the first direction is different from the second direction; and
a controller, coupled to the plurality of memory cell strings, and configured to:
set one of the plurality of first memory cell strings as a selected memory cell string, in a first phase, set a first bit line voltage on the first common bit line to be within a first set voltage range, and set a second bit line voltage on the second common bit line to be higher than the first set voltage range; and
in a second phase, provide a programming voltage to a word line corresponding to a selected memory cell on the selected memory cell string.

10. The memory device according to claim 9, wherein the controller is further configured to:
in the first phase, set the first bit line voltage to be within the first set voltage range to discharge a channel of the selected memory cell string.

11. The memory device according to claim 10, wherein the controller is further configured to:
determine a voltage value of the first bit line voltage according to a threshold voltage of a memory cell string selection switch of the plurality of first memory cell strings.

12. The memory device according to claim 9, wherein the controller is further configured to:
in the first phase, set the second bit line voltage to be higher than the first set voltage range to mask the plurality of second memory cell strings.

13. The memory device according to claim 9, wherein the controller is further configured to:
in the first phase, set a first source line voltage on the first common source line corresponding to the selected memory cell string to be within a second set voltage range, and set a source line voltage on the second common bit line to be higher than the second set voltage range.

14. The memory device according to claim 9, wherein the controller is further configured to:
set a source line voltage on the second common bit line to be higher than the second set voltage range to mask the plurality of fourth memory cell strings.

15. The memory device according to claim 9, wherein the controller is further configured to:
provide a pass voltage to word lines of a plurality of unselected memory cells in the selected memory cell string.

16. The memory device according to claim 9, wherein the first phase is a gate-induced-drain-leakage current boost and channel discharge phase, and the second phase is a programming voltage boost phase.
